(19) United States
(12) Patent Application Publication
(10) Pub. No.: US 2025/0252230 A1
(43) Pub. Date: Aug. 7, 2025

(54) SIMULATION SYSTEM AND COMPUTER-READABLE MEDIUM

(71) Applicant: TOYOTA JIDOSHA KABUSHIKI KAISHA, Aichi-ken (JP)

(72) Inventors: Takahiro SAKURAI, Nagoya-shi (JP); Satoshi TANABE, Tokyo-to (JP); Kensuke MATSUMOTO, Nagoya-shi (JP); Yuki ICHIOKA, Kawasaki-shi (JP)

(21) Appl. No.: 19/041,997

(22) Filed: Jan. 31, 2025

(30) Foreign Application Priority Data
Feb. 7, 2024 (JP) 2024-017402

(51) Int. Cl. G06F 30/20; G06Q 10/067

(52) U.S. Cl. CPC G06F 30/20; G06Q 10/067

(57) ABSTRACT

Processing to select a production collaborator of a simulation is performed. In the processing to select a production collaborator, an aptitude level of a practical worker for a simulation task set in association with a real task constituting an operation performed in a line is calculated based on historical data of a simulation cooperation by the practical worker and historical data of a line design planning by the practical worker. In addition, a leading candidate of the production collaborator is specified based on the calculated aptitude level. Then, information on the identified leading candidate is transmitted to a computer of a producer of the simulation.

The present application claims priority under 35 U.S.C. § 119 to Japanese Patent Application No. 2024-017402, filed on Feb. 7, 2024, the content of which application is incorporated herein by reference in their entirety.

### TECHNICAL FIELD

The present disclosure relates to a system and a computer-readable medium for performing a simulation.

### BACKGROUND

JP2022015852A discloses an operation management system for performing simulation. In the simulation of this system, the number of tasks that have been not executed (unexecuted tasks) among a plurality of tasks constituting a predetermined operation is calculated based on a required time of each of the plurality of tasks, an operable time of each of multiple workers, and a process capacity of each of these workers. Then, when the number of the unexecuted tasks is larger than a reference, a warning is issued. In the calculation of the number of the unexecuted tasks, priorities of the workers are used to assign the multiple workers to each of the plurality of tasks.

Examples of the documents showing the technical level in the technical field related to the present disclosure include JP2018026069A, in addition to JP2022015852A.

Consider a simulation of a line of facility such as a factory, a distribution warehouse, and a distribution center. At least one task set in this simulation correspond to at least one real task constituting an operation performed in the line. Here, the simulation of the line is produced by a producer who looks down the entire line, such as a content of the operation performed in the line and the order of processes of the real task constituting the operation. However, the producer is a person in charge of the production, and is not necessarily familiar with the practical work of the real task processes. Therefore, a cooperation of practical workers engaged in the real task is indispensable for setting a task for simulation (hereinafter, also referred to as a “simulation task”) and inputting and adjusting a parameter specific to the simulation task.

Consider a case where a person who cooperates in the production of the simulation, such as setting of the simulation task and inputting and adjusting the parameter unique to the simulation task (hereinafter, also referred to as a “production collaborator”), is selected from the practical workers. When a scale of the simulation is small, it seems easy for the producer to designate an appropriate production collaborator from among the practical workers. However, when the scale of the simulation is large, the number of candidates for the production collaborator is increased with an increase in the total number of real tasks constituting the operation and the total number of operations themselves, and the selection of the production collaborator is complicated. This aspect is not present in the prior art and therefore leaves room for improvement.

An object of the present disclosure is to provide a technique capable of appropriately selecting a production collaborator of a simulation from among practical workers engaged in a real task constituting an operation performed in a line regardless of the scale of the simulation.

### SUMMARY

A first aspect of the present disclosure is a simulation system for performing a simulation on a line and has the following features.

The simulation system includes one or more memory devices and one or more processors. The one or more memory devices are configured to store data related to a practical worker engaged in at least one real task constituting an operation performed in the line. The one or more processors are configured to perform processing to select a production collaborator of the simulation for each of at least one simulation task set in association with the at least one real task based on the data related to the practical worker.

The data related to the practical worker includes historical data of a simulation cooperation by the practical worker and historical data of a line design planning by the practical worker.

The processing to select the production collaborator includes processing to calculate an aptitude level of the practical worker for the simulation task for each simulation task based on the historical data of the simulation cooperation and the historical data of the line design planning, processing to specify a leading candidate of the production collaborator for each simulation task based on the aptitude level, and processing to transmit information on the leading candidate to a computer of a producer of the simulation.

A second aspect of the present disclosure is a computer-readable medium storing a simulation program and has the following features.

The simulation program causes a computer to perform processing to select a production collaborator for simulation on a line.

In the processing to select the production collaborator, the production collaborator is selected for each of at least one simulation task set in association with at least one real task based on data related to a practical worker engaged in the at least one real task constituting an operation performed in the line.

The data related to the practical worker includes historical data of a simulation cooperation by the practical worker and historical data of a line design planning by the practical worker.

The processing to select the production collaborator includes processing to calculate an aptitude level of the practical worker for the simulation task for each simulation task based on the historical data of the simulation cooperation and the historical data of the line design planning, processing to specify a leading candidate of the production collaborator for each simulation task based on the aptitude level, and processing to transmit information on the leading candidate to a computer of a producer of the simulation.

According to the present disclosure, the processing to select the production collaborator of the simulation is performed. In this processing, the leading candidate of the production collaborator is specified based on the aptitude level of the practical worker for the simulation task, and the information on the leading candidate is transmitted to the computer of the producer of the simulation. That is, the leading candidate of the production collaborator is proposed to the producer. Therefore, not only when the scale of the simulation is small, but also when the scale is large, the producer can appropriately select the production collaborator. This leads to an improvement in the accuracy of the simulation output.

### BRIEF DESCRIPTION OF THE DRAWINGS

FIG. 1 is a diagram illustrating an outline of a simulation system according to an embodiment;

FIG. 2 is a diagram showing an example of an aptitude level for a task of a worker;

FIG. 3 is a diagram illustrating a configuration example of the simulation system according to the embodiment;

FIG. 4 is a diagram illustrating a configuration example of worker data;

FIG. 5 is a flow chart illustrating an example of computer processing particularly relevant to the embodiment; and

FIG. 6 is a flow chart illustrating an example of computer processing particularly relevant to the embodiment.

### DESCRIPTION OF EMBODIMENT

Hereinafter, an embodiment of the present disclosure will be described with reference to the drawings. In the drawings, the same or corresponding parts are denoted by the same reference numerals, and the description thereof will be simplified or omitted.

### 1. Simulation System

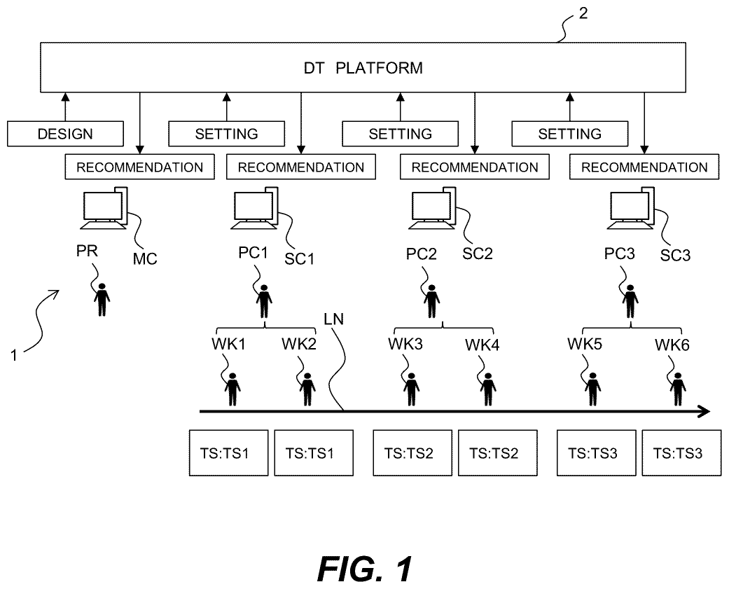

FIG. 1 is a diagram illustrating an outline of a simulation system according to an embodiment of the present disclosure. The simulation system 1 shown in FIG. 1 is a system for performing simulation on a line LN. The line LN is a series of lines for cooperatively performing various operations such as a production, a storage, and packaging of products. The line LN is provided in a site of a factory that mass-produces products, in a site of a distribution warehouse that stores products and raw materials thereof or packs and ships products, and in a site of a distribution center that receives, inspects, stores, picks, packs, and ships products.

Multiple workers are assigned to the line LN. These workers are all “practical workers” engaged in operations performed cooperatively on the line LN. The workers WK1, WK2, WK3, WK4, WK5, and WK6 shown in FIG. 1 are examples of the “practical workers”. Hereinafter, for convenience of description, when any one of the multiple workers assigned to the line LN is referred to, the worker is also referred to as a “worker WKz”.

The workers WK1 and WK2 are responsible for a task TS1. The workers WK3 and WK4 are responsible for a task TS2. The workers WK5 and WK6 are responsible for a task TS3. The tasks TS1, TS2, and TS3 are examples of “at least one real task” constituting an operation performed in the line LN. For example, when the line LN is provided in a distribution center, the tasks TS1, TS2, and TS3 correspond to any one of arrival, inspection, storage, picking, packing, and shipping of products. The tasks TS1, TS2, and TS3 are processed by manual work by the worker WK or a robot operation by the worker WK.

In the simulation system 1, a simulation using digital space (hereinafter, also referred to as a “digital twin simulation” or an “DTS”) is performed. This digital space is reproduced based on a real space in which the line LN is provided. A DT (digital twin) platform 2 shown in FIG. 1 is a configuration for implementing the DTS. Various computers are connected to the DT platform 2, and the DT platform 2 and participants of the DTS exchange information. The various computers include a main computer MC and sub computers SC1, SC2, and SC3.

The main computer MC is a computer of a producer PR responsible for the production of the DTS for the line LN. The main computer MC includes at least one processor and at least one memory device. At least one processor executes various processing. Examples of the at least one processor include a central processing unit (CPU), a graphics processing unit (GPU), an application specific integrated circuit (ASIC), and a field-programmable gate array (FPGA). The at least one memory device stores various data. Examples of the memory device include a volatile memory, a nonvolatile memory, a hard disk drive (HDD), and a solid state drive (SSD). Various programs are stored in at least one memory device. The various programs may be stored in a computer-readable medium.

The producer PR is a person who looks down on the entire line LN, such as the content of the operation performed in the line LN and the order of processing of the tasks constituting the operation. The producer PR sets a task for DTS (i.e., a simulation task for DTS) in association with tasks (i.e., the tasks TS1, TS2, and TS3) constituting an operation to be executed in the line LN and performs a design input of DTS. In response to the design input by the producer PR or in order to assist the design input, various input recommendations are output from the DT platform 2 to the main computer MC.

In order to implement DTS, it is necessary to input and adjust parameters unique to a task for DTS in consideration of the actual situation of each of tasks TS1, TS2, and TS3. Computers for performing the input and adjustment are sub computers SC1, SC2, and SC3. The sub computers SC1, SC2 and SC3 are computers of production collaborators PC1, PC2 and PC3, respectively. Each of the configurations of these sub-computers is basically the same as that of the main computer MC.

The production collaborators PC1, PC2 and PC3 are elected from workers engaged in the tasks TS1, TS2 and TS3. In the example shown in FIG. 1, the production collaborator PC1 is the worker WK1 or WK2, the production collaborator PC2 is the worker WK3 or WK4, and the production collaborator PC3 is the worker WK5 or WK6. The production collaborators PC1, PC2, and PC3 perform setting input such as input and adjustment of parameters unique to tasks for which the production collaborators PC1, PC2, and PC3 are in charge, based on various input recommendations output from the DT platform 2 to the sub computers SC1, SC2, and SC3, respectively.

### 2. Aptitude Level

A worker who is familiar with the practical work of the task TS1 (e.g., a worker in experienced) can be a candidate for the production collaborator PC1. This is the same for the candidates of the production collaborators PC2 and PC3. If the DTS is small in size and the total number of tasks is small, such a person may be extracted from the multiple workers and assigned to the production collaborator. However, when the scale of the DTS increases, the total number of tasks and the total number of candidates of production collaborators increase. Even a worker who is familiar with the practical work of a task is not suitable as a production collaborator if he or she is not familiar with simulation affairs. On the other hand, even if the worker has shallow practical experience of the task, there is a person who is suitable for the production collaborator.

Therefore, in the embodiment, an attitude level AL of the worker WKz with respect to the DTS is calculated based on data related to the worker WK (hereinafter referred to “worker data”). Since the production collaborator is elected for each task, the aptitude level AL is also calculated for each task. The aptitude level AL is calculated by using a calculation formula having, for example, a history of cooperation with respect to the DTS of the worker WKz and a history of the design plan with respect to the line of the worker WKz as variables.

The history of collaboration for DTS is, for example, a past record that worker WKz is elected as the production collaborator for the same task as the task constituting the operation performed in line LN and the task to be a target of the calculation of the aptitude level AL. It is expected that a person having experience as a production collaborator will have an understanding of simulation affair and will properly act as a production collaborator.

The history of collaboration for DTS may be a past record of worker WKz being elected as a production collaborator for a task that constitutes an operation performed in line LN and is similar to a task for which the aptitude level AL is calculated. The past performance of the same task as the task constituting the operation performed in a line different from the line LN and the task serving as the target of the calculation of the aptitude level AL may be used as the history.

The history of the design plan for the line is, for example, a past record of the worker WKz's work on the design and plan of the line LN or a line different from the line. The experience involved in design and planning is close to that of looking down on the whole line. Therefore, it is expected that a person having such experience understands the intention of the simulation produced by the producer PR and appropriately plays a role as a production collaborator.

The history of the cooperation with the DTS can be said to be a direct history of the DTS, whereas the history of the design plan for the line can be said to be an indirect history of the DTS. By calculating the aptitude level AL using a calculation formula in which such two kinds of history are variables, the aptitude of the worker WKz for the task that is the target of the calculation of the aptitude level AL is evaluated.

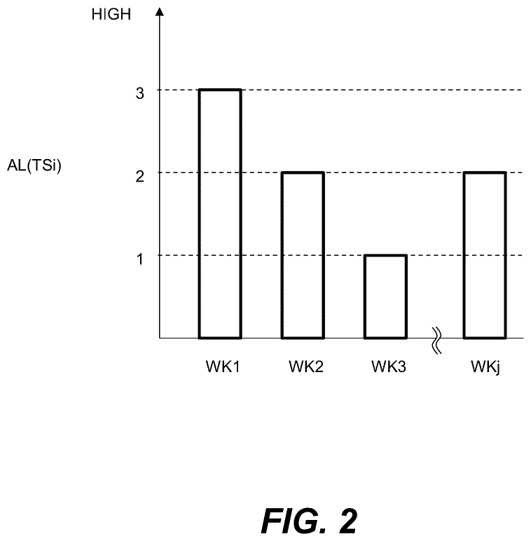

FIG. 2 is a diagram showing an example of the attribute level AL (TSi) for a task TSi (“i” is a positive integer) of the worker WKz. In FIG. 2, the values of the aptitude level AL (TSi) of the workers WK1, WK2, WK3, and WKj (“j” is a positive integer greater than 3) are shown. In the example shown in FIG. 2, the aptitude level AL (TSi) of the worker WK1 is the highest, and that of the worker WK3 is the lowest. From this, it is understood that the worker WK1 is the leading candidate of the production collaborator of the task TSi.

In the embodiment, the leading candidate CD of the production collaborator PC is specified for all tasks constituting the operation performed in the line LN. When the leading candidate CD is specified, information on the leading candidate CD is transmitted to the main computer MC. The producer PR approves the leading candidate CD included in the information on the leading candidate CD as the production collaborator PC, or selects the production collaborator PC with reference to the information on the leading candidate CD. Thus, the production collaborator PC is selected.

As described above, in the embodiment, the production collaborator PC is selected based on the aptitude level AL (TSi). A configuration example for selecting a production collaborator PC of the DTS will be described below.

### 3. Configuration Example

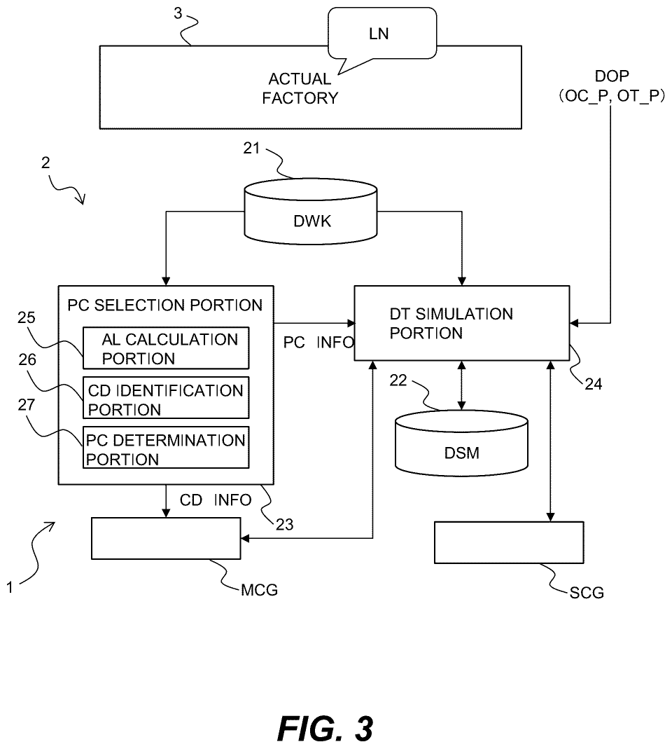

FIG. 3 is a diagram illustrating a configuration example of the simulation system according to the embodiment. The simulation system 1 shown in FIG. 3 includes a simulation platform 2, a main computer group MCG (a plurality of the main computers MC), and a sub computer group SCG (a plurality of the sub computers SC) as a configuration for performing a simulation (i.e., the digital twin simulation) using a digital space that reproduces a real space in an actual plant 3 in which the line LN is provided.

The DT platform 2 is a computer including at least one processor and at least one memory device. Examples of the at least one processor and the at least one memory device are the same as the examples of the processor and the memory device included in the main computer MC. However, the memory device of the DT platform 2 stores a program for executing the processing to select the production collaborator PC, the DTS, and other data processing. These programs may be stored in a computer-readable recording medium.

In the example shown in FIG. 3, the DT platform 2 includes databases 21 and 22, a PC selection portion 23, and a DT (digital twin) simulation portion 24. The databases 21 and 22 are formed in, for example, a hard disk or a flash memory. The database 21 stores worker data DWK. The database 22 stores simulation data DSM.

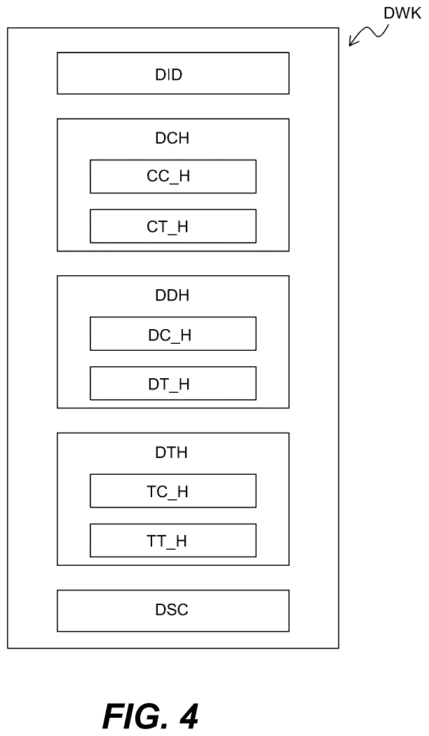

FIG. 4 is a diagram illustrating a configuration example of the worker data DWK. In the example shown in FIG. 4, the worker data DWK includes identification data DID, cooperation history data DCH, design planning history data DDH, task history data DTH, and schedule data DSC.

The identification information DID is used to identify the worker WKz. The cooperation history data DCH represents history of cooperation with the DTS by the worker WKz. The cooperation history data DCH includes cooperation content data CC_H and cooperation time data CT_H. The cooperation content CC_H represents the contents of the task when worker WKz is selected as the production collaborator. The cooperation content data CC_H is generated in association with the line. The cooperation time date CT_H is date relating to a period in which the worker WKz is selected as the production collaborator or a time when the worker SL acts as the production collaborator. The cooperation time data CT_H is generated for each task content.

The design planning history data DDH represents the history of the design and planning of the line by the worker WKz. The design planning history data DDH includes design planning content data DC_H and design planning time data DT_H. The design planning content data DC_H represents the outline of the design planning of the line in which the worker WKz is engaged. The design planning content data DC_H is generated in association with the line in which the worker WKz is engaged. The design planning time data-DT_H is related to the time when the worker WKz is engaged in the design planning. The design planning time data DT_H is generated for each content of the design plan.

The task history data DTH represents history of tasks that the worker WKz has engaged in. The task history data DTH includes task content data TC_H and task time data TT_H. The task content TC_H represents the content of the task that the worker WKz has engaged in. The task content data TC_H is generated in association with the line. The task time date TT_H represents date relating to the time of the task that the worker WKz has engaged in. The task time data TT_H is generated for each content of the task engaged in by the worker WKz.

The schedule data DSC represents a schedule of the worker WKz. The schedule of the worker WKz is, for example, a work schedule of th worker WKz for a certain period (e.g., one day, one week, or one month). The work schedule includes information such as a time zone in which the operation is scheduled to be arranged in the line LN, a time zone in which the operation is scheduled to be engaged in a task other than tasks constituting the operation performed in the line LN, and a time zone in which the operation is scheduled to take a break.

Returning to FIG. 3, the simulation data DSM stored in the database 22 includes various data necessary for implementing the DTS. Data necessary for implementing the DTS includes data of a model for the DTS. The model for the DTS is built by the producer PR. The data required for implementing the DTS also includes parameters of a model for the DTS. The input of these parameters is performed by the producer PR and the production collaborator PC. The model for the DTS and the parameters of the model may be adjusted by analysis of the results of the DTS. The simulation data DSM also includes result data and analysis data of the DTS.

The function of the PC selection portion 23 is realized by, for example, the at least one processor included in the DT platform 2. The PC selection portion 23 selects the production collaborator from the worker WKz. As a configuration for selecting a production collaborator, the PC selection portion 23 includes an AL calculation portion 25, a CD identification portion 26, and a PC determination portion 27.

The AL calculation portion 25 calculates the aptitude level AL (TSi) for the task TSi of the worker WKz based on the worker data DWK stored in the database 21. When calculating the aptitude level AL (TSi), data constituting the cooperation history data DCH (i.e., the cooperation content data CC_H and the cooperation time data CT_H) is referred to, and data related to the task TSi (i.e., the task constituting the operation performed in the line LN and also the task as a target of calculation of the aptitude level AL) is extracted for each worker. In addition, data (i.e., the design planning content data DC_H and the design planning time data DT_H) constituting the design planning history data DDH is referred to, and data related to the design planning is extracted for each worker.

Then, the data extracted for each worker is substituted into a calculation formula (AL (TSi)=f (CC_H, CT_H, DC_H, DT_H)) with the cooperation history data DCH and the design planning history data DDH as variables. Thus, the aptitude level AL (TSi) is calculated.

The CD identification portion 26 compares the aptitude level AL (TSi) calculated by the AL calculation portion 25 between the workers to identify a leading candidate CD (TSi). The leading candidate CD (TSi) is, for example, a worker WKz having the highest aptitude level AL (TSi). In another example, at least two leading candidate CDs (TSi) are identified. In this case, the leading candidate CD (TSi) is specified in order from the top of the aptitude level AL (TSi). The CD identification portion 26 generates information on the identified leading candidate CD (TSi) (hereinafter, also referred to as “CD information”).

Since there are a plurality of tasks constituting the operation executed in the line LN, a leading candidate CD (TSx) of a certain task TSx may overlap a leading candidate CD (TSy) of another task TSy (x and y are natural numbers). In addition, in an example in which at least two leading candidate CDs are specified, the possibility of the occurrence of the overlap increases. In this case, the CD identification portion 26 generates duplicate information on the leading candidate CD.

The PC determination portion 27 transmits the CD information generated by the CD identification portion 26 to the main computer MC. When the duplicate information is generated, the PC determination portion 27 transmits the duplicate information to the main computer MC together with the CD information. The producer PR operates the main computer MC to approve the leading candidate CD included in the CD information as the production collaborator PC, or selects the production collaborator PC by referring to the CD information. When receiving the approval or selection information from the main computer MC, the PC determination portion 27 determines the production collaborator PC based on this information. Information on the production collaborator PC determined in this way (hereinafter, also referred to as “PC-information”) is transmitted to the DT simulation portion24.

The function of the DT simulation portion24 is realized by, for example, at least one processor included in the DT platform 2. The DT simulation portion24 performs the DTS. In this DTS, first, a worker WKz is assigned to a task constituting an operation being executed in the line LN. A worker WKz may be assigned to a task constituting an operation scheduled to be executed in the line LN. When the worker WKz is assigned, the schedule data DSC and the task history data DTH are referred to as appropriate.

The operation being executed or scheduled to be executed in the line LN and the tasks constituting the operation are specified from operation plan data DOP of the line LN. Here, the operation plan data DOP is separately set by, for example, a computer included in the actual factory 3. The operation plan data DOP includes, for example, data of operation content OC_P being executed (or scheduled to be executed) in the line LN and data of time OT_P for executing (or scheduled to be executed) the operation of the operation content OC_P. Therefore, by referring to the data of the operation content OC_P, the operation being executed or to be executed in the line LN and the tasks constituting this operation are specified.

When the worker WKz allocation is completed, the DTS is executed. In the DTS, for example, a future state in the line LN is predicted. The future state includes the efficiencies of all operations performed in the line LN, the efficiencies of tasks constituting the operations, the load factor of the worker WKz engaged in the tasks, and the like.

### 4. Processing Example

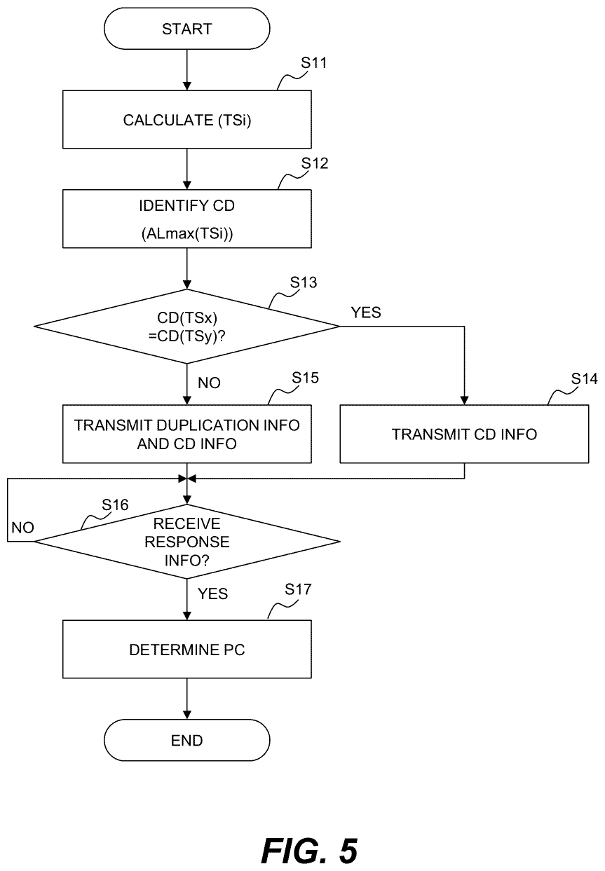

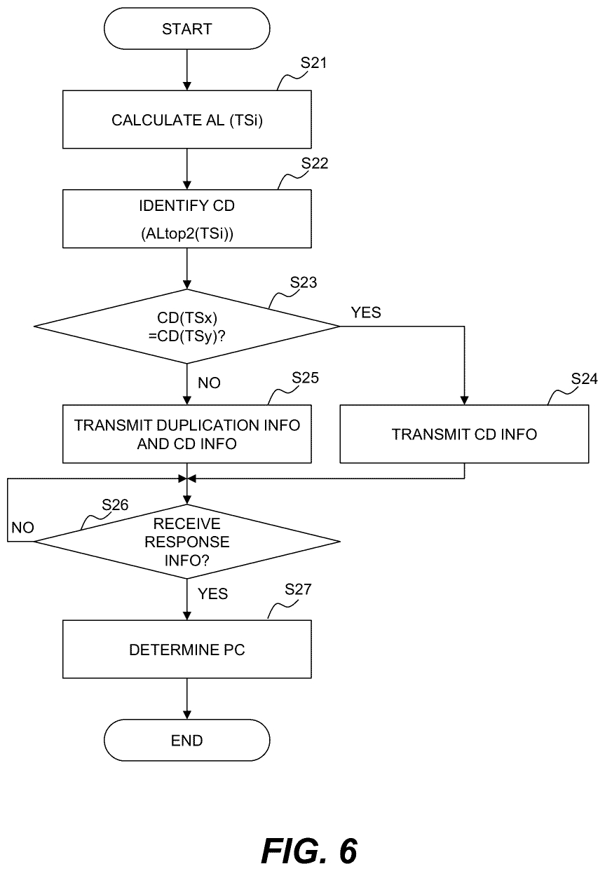

FIGS. 5 and 6 are flow charts illustrating an example of computer processing that is particularly relevant to the embodiment. The routine shown in FIG. 5 or 6 is repeatedly executed at a predetermined cycle by at least one processor included in the DT platform 2, for example.

In the routine shown in FIG. 5, first, the attitude level AL (TSi) is calculated (step S11). The calculation of the aptitude level AL (TSi) is performed based on the cooperation history data DCH and the design planning history data DDH stored in the database 21. The calculation of the aptitude level AL (TSi) is performed using the calculation formula with the cooperation history data DCH and the design planning history data DDH as variables, which is described in the description of the AL calculation portion 25. The calculation of the aptitude level AL (TSi) is performed for each worker.

Subsequent to the processing of step S11, the leading candidate CDs are identified (step S12). The leading candidate CDs are identified by comparing the values of the attribute level AL (TSi) calculated in the process of step S11 between the workers. In the process of step S12, the worker having the highest value of the aptitude level AL (TSi) is identified as the leading candidate CD. The leading candidate CD is specified for each task.

Subsequent to the processing of step S12, it is determined whether or not the leading candidate CD overlaps between the tasks (step S13). When the leading candidate CD (TSx) of the production collaborator PC for the task TSx and the leading candidate CD (TSy) of the production collaborator PC for the task TSy overlap, duplicate information is generated. The duplicate information includes information on the tasks TSx and TSy and information on the leading candidate CD common to these tasks. The duplicate information may include information on the aptitude levels AL (TSx) and AL (TSy) calculated in the process of step S11. When the information on the aptitude levels AL (TSx) and AL (TSy) is included in the duplicate information, the information on the workers of the top several names of the aptitude levels AL (TSx) and AL (TSy) may be added to the duplicate information as the information on the preliminary candidates of the production collaborator PC.

If the judgment result in step S13 is positive, information on the leading candidate CD (CD information) is transmitted to the main computer MC (step S14). Otherwise, duplicate information is transmitted to the main computer MC in addition to the information on the leading candidate CDs (step S15).

Subsequent to the processing of step S14 or S15, it is determined whether or not response information (i.e., approval or selection information) has been received from the main computer MC (step S16). The process of step S16 is repeated until the response information is received. If the judgment result in step S16 is positive, the production collaborator is determined (step S17). The production collaborator PC is determined based on the response information received in the processing of step S16.

In the processing of the routine shown in FIG. 6, first, the aptitude level AL (TSi) is calculated (step S21). The content of the processing in step S21 is the same as those of the processing in step S11 in FIG. 5.

Subsequent to the processing of step S21, the leading candidate CDs are identified (step S22). The leading candidate CDs are identified by comparing the values of the attribute level AL (TSi) calculated in the processing of step S21 between the workers. In the processing of step S22, the top two workers of the aptitude level AL (TSi) are specified as the leading candidate CDs. The leading candidate CDs are specified for each task.

Subsequent to the processing of step S22, it is determined whether or not the leading candidate CD overlaps between the tasks (step S23). The content of the processing in step S23 is basically the same as that of the processing in step S13 in FIG. 5. However, in the processing of step S23, it is desirable that the order information on the leading candidate CDs common to the plurality of tasks is added to the duplicate information. The information on the aptitude levels AL (TSx) and AL (TSy) may be included in the duplicate information, and the information on the preliminary candidates of the top several candidates (excluding the leading candidate CDs) of the aptitude levels AL (TSx) and AL (TSy) may be added to the duplicate information, which is the same as the processing in step S13.

If the judgment result in step S23 is positive, information on the leading candidate CD (CD information) is transmitted to the main computer MC (step S24). Otherwise, duplicate information is transmitted to the main computer MC in addition to the information on the leading candidate CDs (step S25).

Subsequent to the processing of step S24 or S25, it is determined whether or not response information (i.e., approval or selection information) has been received from the main computer MC (step S26). The content of the processing in step S26 is the same as that of the processing in step S16 in FIG. 5. If the judgment result in step S16 is positive, the production collaborator is determined (step S27). The production collaborator PC is determined based on the response information received in the processing in step S26.

### 5. Effect

According to the embodiment described above, the processing to select the production collaborator PC is performed. According to this processing, the leading candidate CD is identified based on the attribute level AL of the worker WKz for the DTS, and information on the leading candidate CD is transmitted to the main computer MC. That is, the leading candidate CD is proposed to the producer PR. Therefore, not only when the scale of simulation is small, but also when the scale is large, the producer PR can appropriately select the production collaborator PC. This leads to an improvement in the accuracy of the DTS output.

What is claimed is:

1. A simulation system for performing a simulation on a line, comprising:
one or more memory devices configured to store data related to a practical worker engaged in at least one real task constituting an operation performed in the line; and
one or more processors configured to perform processing to select a production collaborator of the simulation for each of at least one simulation task set in association with the at least one real task based on the data related to the practical worker,
wherein the data related to the practical worker includes historical data of a simulation cooperation by the practical worker and historical data of a line design planning by the practical worker,
wherein the processing to select the production collaborator includes:
processing to calculate an aptitude level of the practical worker for the simulation task for each simulation task based on the historical data of the simulation cooperation and the historical data of the line design planning;
processing to specify a leading candidate of the production collaborator for each simulation task based on the aptitude level; and
processing to transmit information on the leading candidate to a computer of a producer of the simulation.

2. The system according to claim 1,
wherein the processing to identify the leading candidate further includes processing to compare the aptitude levels calculated for the respective simulation tasks between the practical workers,
wherein the practical worker having a highest value of the aptitude level in the simulation task is identified as the leading candidate.

3. The system according to claim 2,
wherein the at least one real task includes at least two real tasks,
wherein, in the processing to identify the leading candidate, the processor is further configured to perform processing to generate duplicate information on the leading candidate when the practical worker having the highest aptitude level is identified in a duplicated manner between at least two simulation tasks set in association with the at least two real tasks,
wherein when the duplicate information is generated, the duplicate information is further transmitted to the computer of the producer in the processing to transmit the information on the leading candidate.

4. The system according to claim 1,
wherein the processing to identify the leading candidate further includes processing to compare the aptitude levels calculated for the respective simulation tasks between the practical workers,
wherein at least two practical workers from the top of the values of the aptitude level are identified as the leading candidates in the simulation task.

5. The system according to claim 4,
wherein the at least one real task includes at least two real tasks,
wherein, in the processing to identify the leading candidate, the processor is further configured to perform processing to generate duplicate information on the leading candidate when the practical worker having the highest aptitude level is identified in a duplicated manner between at least two simulation tasks set in association with the at least two real tasks,
wherein at least two practical workers from the top of the values of the aptitude level are identified as the leading candidates in the simulation task.

6. A non-transitory computer-readable medium storing a simulation program, the simulation program causing a computer to perform processing to select a production collaborator for simulation on a line,
wherein, in the processing to select the production collaborator, the production collaborator is selected for each of at least one simulation task set in association with at least one real task based on data related to a practical worker engaged in the at least one real task constituting an operation performed in the line,
wherein the e data related to the practical worker includes historical data of a simulation cooperation by the practical worker and historical data of a line design planning by the practical worker,
wherein the processing to select the production collaborator includes:
processing to calculate an aptitude level of the practical worker for the simulation task for each simulation task based on the historical data of the simulation cooperation and the historical data of the line design planning;
processing to specify a leading candidate of the production collaborator for each simulation task based on the aptitude level; and
processing to transmit information on the leading candidate to a computer of a producer of the simulation.
